(19) United States
(12) Patent Application Publication
(10) Pub. No.: US 2023/0170666 A1
(43) Pub. Date: Jun. 1, 2023

(54) SEMICONDUCTOR LASER DEVICE

(71) Applicant: Panasonic Holdings Corporation, Osaka (JP)

(72) Inventors: Hideo YAMAGUCHI, Kyoto (JP); Masaharu FUKAKUSA, Osaka (JP)

(21) Appl. No.: 18/099,483

(22) Filed: Jan. 20, 2023

Related U.S. Application Data
(63) Continuation of application No. PCT/JP2021/026785, filed on Jul. 16, 2021.

(30) Foreign Application Priority Data
Aug. 5, 2020 (JP) 2020-133417

(51) Int. Cl. H01S 5/02326; H01S 5/0683

(52) U.S. Cl. CPC H01S 5/02326; H01S 5/0683

(57) ABSTRACT

A semiconductor laser device includes: a semiconductor laser element including an emitter that emits emission light; a lens that transmits the emission light emitted from the emitter; a driver that supports the lens in a state in which a position and an orientation of the lens are changeable; a detector that detects an intensity distribution of the emission light emitted from the emitter and transmitted through the lens; and a controller that, based on a detection result of the detector, controls at least one of the position or the orientation of the lens by driving the driver to cause the intensity distribution of the emission light detected by the detector to be a predetermined light intensity distribution.

### CROSS REFERENCE TO RELATED APPLICATIONS

This is a continuation application of PCT International Application No. PCT/JP2021/026785 filed on Jul. 16, 2021, designating the United States of America, which is based on and claims priority of Japanese Patent Application No. 2020-133417 filed on Aug. 5, 2020. The entire disclosures of the above-identified applications, including the specifications, drawings and claims are incorporated herein by reference in their entirety.

### FIELD

The present disclosure relates to a semiconductor laser device.

### BACKGROUND

Patent Literature (PTL) 1 discloses a semiconductor laser device including: a semiconductor laser element; a reflector that reflects laser light output from the semiconductor laser element to be in the optical axis direction on the optical fiber side; a photoreceiver that receives the laser light from the reflector; an optical fiber that transmits the laser light to the outside; and a controller that moves the reflector to adjust the optical axis based on the light intensity of the laser light received by the photoreceiver.

In this way, the laser light reflected by the reflector can be appropriately introduced into the optical fiber. High efficiency of coupling of the laser light to the optical fiber can thus be achieved.

### CITATION LIST

Patent Literature
PTL 1: Japanese Unexamined Patent Application Publication No. 2004-93971
PTL 2: Japanese Unexamined Patent Application Publication No. 2000-137139

### SUMMARY

### Technical Problem

When a light source such as a semiconductor laser element emits light, the light source generates heat. The light source, a base on which the light source is placed, etc. expand due to the heat generated by the light source. Thus, when the light source emits light, the position of the light passing through an optical system such as a condensing lens deviates from the desired position. There is accordingly a problem in that the optical axis of light (for example, laser light) emitted from the semiconductor laser device deviates from the desired position depending on the amount of light emitted from the light source, for example, depending on the amount of power supplied to the light source to cause the light source to emit light.

The present disclosure provides a semiconductor laser device that can maintain the relative positional relationship between a semiconductor laser element that emits light and a lens that transmits the light, in an appropriate state.

### Solution to Problem

A semiconductor laser device according to an aspect of the present disclosure includes: a semiconductor laser element including an emitter that emits light; a lens that transmits the light emitted from the emitter; a driver that supports the lens in a state in which a position and an orientation of the lens are changeable; a detector that detects an intensity distribution of the light emitted from the emitter and transmitted through the lens; and a controller that, based on a detection result of the detector, controls at least one of the position or the orientation of the lens by driving the driver to cause the intensity distribution of the light detected by the detector to be a predetermined light intensity distribution.

These general and specific aspects may be implemented using a system, a method, an integrated circuit, a computer program, or a computer-readable recording medium such as CD-ROM, or any combination of a system, a method, an integrated circuit, a computer program, and a recording medium.

### Advantageous Effects

The semiconductor laser device according to an aspect of the present disclosure can maintain the relative positional relationship between a semiconductor laser element that emits light and a lens that transmits the light, in an appropriate state.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram schematically illustrating the structure of a semiconductor laser device according to an embodiment.

FIG. 2 is a perspective diagram illustrating a light source module included in the semiconductor laser device according to the embodiment.

FIG. 3 is a sectional diagram illustrating the light source module included in the semiconductor laser device according to the embodiment, taken along line III-III in FIG. 2.

FIG. 4 is a diagram schematically illustrating the intensity distribution of light in the case where a lens is in a reference state.

FIG. 5A is a diagram schematically illustrating the intensity distribution of light in the case where the lens deviates to the negative side of a first axis.

FIG. 5B is a diagram schematically illustrating the intensity distribution of light in the case where the lens deviates to the positive side of the first axis.

FIG. 6A is a diagram schematically illustrating the intensity distribution of light in the case where the lens deviates to the negative side of a second axis.

FIG. 6B is a diagram schematically illustrating the intensity distribution of light in the case where the lens deviates to the positive side of the second axis.

FIG. 7A is a diagram schematically illustrating the intensity distribution of light in the case where the lens deviates to the negative side of an emission axis.

FIG. 7B is a diagram schematically illustrating the intensity distribution of light in the case where the lens deviates to the positive side of the emission axis.

FIG. 8A is a diagram schematically illustrating the intensity distribution of light in the case where the lens deviates to the negative side of a first rotation axis.

FIG. 8B is a diagram schematically illustrating the intensity distribution of light in the case where the lens deviates to the positive side of the first rotation axis.

FIG. 9A is a diagram schematically illustrating the intensity distribution of light in the case where the lens deviates to the negative side of a second rotation axis.

FIG. 9B is a diagram schematically illustrating the intensity distribution of light in the case where the lens deviates to the positive side of the second rotation axis.

FIG. 10 is a flowchart illustrating a procedure by the semiconductor laser device according to the embodiment.

FIG. 11 is a perspective diagram illustrating a light source module according to a variation.

FIG. 12 is a sectional diagram illustrating the light source module according to the variation.

### DESCRIPTION OF EMBODIMENTS

Embodiments of a semiconductor laser device according to the present disclosure will be described below with reference to the drawings. The embodiments disclosed below are all examples, and are not intended to limit the semiconductor laser device according to the present disclosure. The numerical values, shapes, materials, structural elements, the arrangement and connection of the structural elements, steps, the order of steps, etc. shown in the following embodiments are mere examples, and do not limit the scope of the present disclosure.

In the embodiments disclosed below, description detailed more than necessary may be omitted. For example, detailed description of well-known matters or repeated description of the substantially same structures may be omitted. This is to avoid unnecessarily redundant description and facilitate the understanding of a person skilled in the art.

Each drawing is a schematic and does not necessarily provide precise depiction. Hence, for example, the reduction scale is not necessarily consistent among the drawings. The substantially same structural elements are given the same reference marks throughout the drawings, and repeated description of the substantially same structural elements may be omitted or simplified.

In the following embodiments, the terms “upper” and “lower” do not refer to the upward direction (vertically upward) and the downward direction (vertically downward) in absolute space perception. The terms “upper” and “lower” apply not only in the case where two structural elements are arranged apart from each other with another structural element therebetween but also in the case where two structural elements are arranged in close contact with each other.

In the specification and the drawings, the X-axis, the Y-axis, and the Z-axis indicate three axes of a three-dimensional orthogonal coordinate system. In the following embodiments, the Y-axis direction is the vertical direction, and the direction perpendicular to the Y-axis (i.e. the direction parallel to the XY plane) is the horizontal direction. A semiconductor laser element emits light in the Z-axis direction.

In the following embodiments, the term “top view” refers to a view on the mounting surface side from the direction normal to the mounting surface of the base on which the semiconductor laser element is placed.

### Embodiment

### Structure

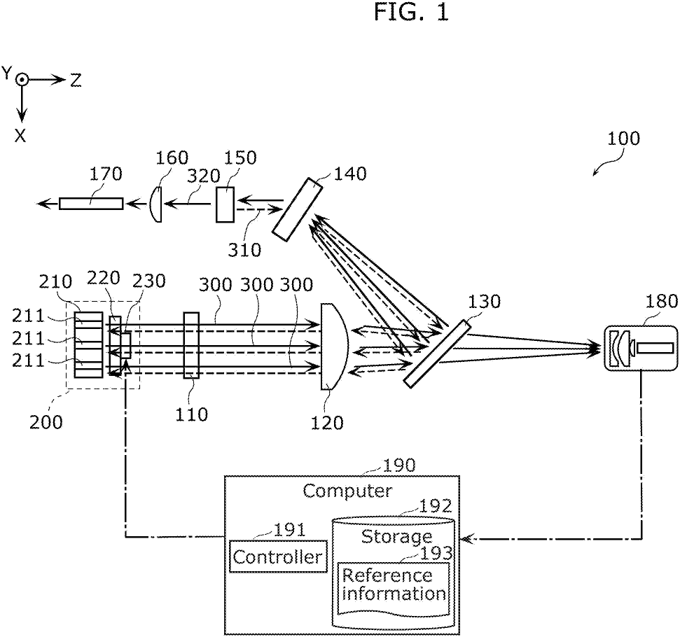

First, the structure of a semiconductor laser device according to an embodiment will be described below, with reference to FIG. 1 to FIG. 3.

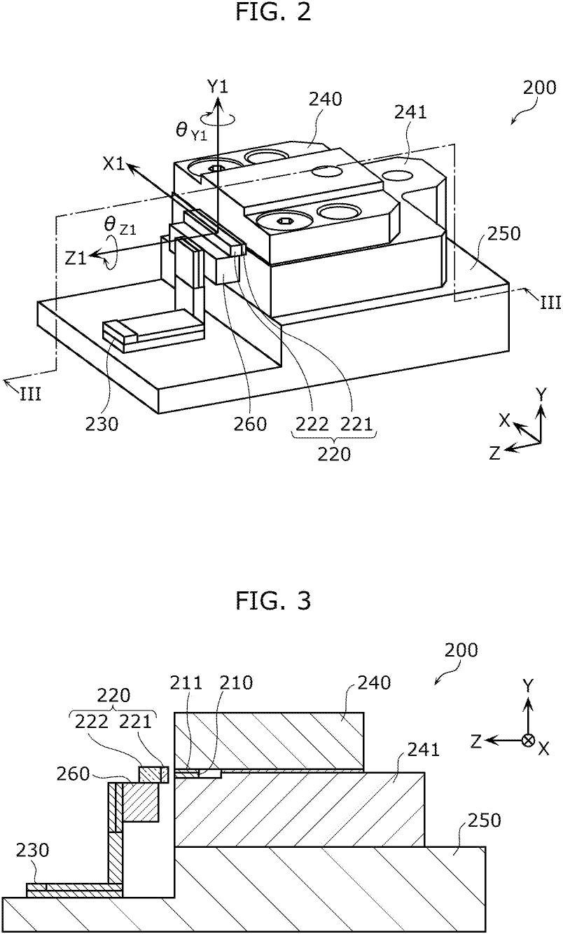

FIG. 1 is a diagram illustrating the schematic structure of semiconductor laser device 100 according to an embodiment. In FIG. 1, computer 190 is illustrated as a functional block. Computer 190 is communicably connected to devices such as detector 180 and driver 230 included in semiconductor laser device 100, via control lines or the like. FIG. 2 is a perspective diagram illustrating light source module 200 included in semiconductor laser device 100 according to the embodiment. FIG. 3 is a sectional diagram illustrating the light source module included in semiconductor laser device 100 according to the embodiment, taken along line III-III in FIG. 2.

Semiconductor laser device 100 is a laser device that emits laser light. Semiconductor laser device 100 is used, for example, as a light source of fabricating equipment that laser-processes an object.

For example, semiconductor laser device 100 includes light source module 200, slow axis collimator lens (SAC) 110, condensing lens 120, half mirror 130, wavelength dispersion element 140, half mirror 150, condensing lens 160, optical fiber 170, detector 180, and computer 190.

Light source module 200 is a light source that emits light (emission light 300).

Light source module 200 includes semiconductor laser element 210, beam twisted lens unit (BTU) 220, driver 230, upper base 240, lower base 241, foundation 250, and support 260.

Semiconductor laser element 210 is a light source that emits emission light 300. Semiconductor laser element 210 includes a plurality of emitters 211.

The plurality of emitters 211 are each a light emitter that emits emission light 300. For example, emission light 300 is laser light. The plurality of emitters 211 are, for example, each a light amplifier that amplifies emission light 300 and emits it in the positive direction of the Z axis. Emitters 211 are, for example, arranged in a line in a first direction (X-axis direction).

The wavelength of emission light 300 emitted by semiconductor laser element 210 may be set to any wavelength. In this embodiment, semiconductor laser element 210 emits blue light. For example, blue light is light whose center wavelength is 430 nm or more and 470 nm or less. Semiconductor laser element 210 forms an external resonator together with half mirror 150. Thus, laser light is emitted from semiconductor laser element 210 as emission light 300.

The number of emitters 211 is one or more, and is not limited.

In this embodiment, semiconductor laser element 210 is a semiconductor laser element array that includes a plurality of emitters 211 each of which emits emission light 300. Semiconductor laser element 210 may be composed of a plurality of laser elements each of which includes one emitter 211.

Semiconductor laser device 100 may not include a structural element for forming an external resonator, such as half mirror 150, as long as it can emit laser light as emission light 300. The material used in semiconductor laser element 210 is not limited. Semiconductor laser element 210 is, for example, a gallium nitride-based semiconductor element.

Semiconductor laser element 210 emits emission light 300 as a result of being supplied with power from an external commercial power source or the like (not illustrated).

Semiconductor laser element 210 is fixed and mounted on the upper surface of lower base 241 by brazing, soldering, or the like. Semiconductor laser element 210 is fixed in a state of being sandwiched between upper base 240 and lower base 241.

Emission light 300 emitted from semiconductor laser element 210 is incident on BTU 220.

BTU 220 is an optical element that condenses (more specifically, collimates) emission light 300 and switches the fast axis direction and the slow axis direction of condensed emission light 300. For example, BTU 220 includes lens 221 and optical member 222.

Lens 221 is a lens that transmits the light emitted from emitter 211. Specifically, lens 221 is a fast axis collimator lens (FAC) that collimates emission light 300 emitted from emitter 211 in the fast axis direction. In this embodiment, lens 221 has emission light 300 emitted from each of the plurality of emitters 211 incident thereon, condenses (collimates) incident emission light 300, and emits condensed (collimated) emission light 300. Emission light 300 emitted from lens 221 is incident on optical member 222.

Optical member 222 is an optical element that switches the fast axis direction and the slow axis direction of emission light 300 emitted from lens 221. Specifically, optical member 222 is a 90° image rotating optical system that rotates emission light 300 condensed (more specifically, collimated) by lens 221 by 90° about the optical axis of emission light 300. Emission light 300 emitted from optical member 222 is incident on slow axis collimator lens 110.

For example, lens 221 and optical member 222 are integrally formed of translucent glass, resin, or the like.

Thus, BTU 220 is an optical system that condenses (collimates), by lens 221, emission light 300 emitted from semiconductor laser element 210 and rotates, by optical member 222, condensed emission light 300 by 90° about the optical axis of emission light 300. An example of BTU 220 is the optical luminous flux converter disclosed in the foregoing PTL 2.

Lens 221 and optical member 222 may be arranged in contact with each other (in other words, integrally formed), or arranged separately from each other. In this embodiment, lens 221 and optical member 222 are arranged in contact with each other.

Although semiconductor laser device 100 includes one BTU 220 in this embodiment, the shape, number, etc. of BTUs 220 included in semiconductor laser device 100 are not limited.

Driver 230 is a device that supports lens 221 in a state in which the position and orientation of lens 221 are changeable. In this embodiment, driver 230 supports BTU 220 via support 260, and adjusts the position and orientation of BTU 220 as a result of being controlled by computer 190. For example, driver 230 is connected (fixed) to support 260 by brazing, soldering, or the like. For example, driver 230 is connected (fixed) to the upper surface of foundation 250 by brazing, soldering, or the like.

Driver 230 is not limited as long as it can adjust the position and orientation of BTU 220. For example, driver 230 is an electric goniometer stage. Alternatively, for example, driver 230 is a magnetic actuator driven magnetically. In this embodiment, driver 230 is an actuator capable of adjusting five axes: an emission axis (Z1-axis in this embodiment) that is an axis parallel to the emission direction (Z-axis direction in this embodiment) of emission light 300 of emitter 211; a first axis (X1-axis in this embodiment) that is an axis parallel to a first direction (X-axis direction in this embodiment) in which the plurality of emitters 211 are arranged; a second axis (Y1-axis in this embodiment) that is an axis parallel to a second direction (Y-axis direction in this embodiment) orthogonal to the emission axis and the first axis; a first rotation axis (θ_{Y1}-axis in this embodiment) that is an axis of a rotation direction about the second axis, and a second rotation axis (θ_{Z1}-axis in this embodiment) that is an axis of a rotation direction about the emission axis.

The X1-axis, the Y1-axis, and the Z1-axis indicate the three axes of the three-dimensional orthogonal coordinate system. For example, the X1-axis is an axis parallel to the X-axis. For example, the Y1-axis is an axis parallel to the Y-axis. For example, the Z1-axis is an axis parallel to the Z-axis. The first direction is the X-axis direction and the X1-axis direction. The second direction is the Y-axis direction and the Y1-axis direction. The emission direction is the Z-axis direction and the Z1-axis direction. The direction in which emitter 211 emits emission light 300 is the positive direction of the Z1-axis. The vertically upward direction is the positive direction of the Y1-axis. The direction in which the plurality of emitters 211 are arranged and that is rightward when the positive side of the Z1-axis is seen from the plurality of emitters 211 is the positive direction of the X1-axis.

For example, the origin of the X1Y1Z1 coordinates is set to coincide with the center of gravity of lens 221.

Upper base 240 is a base that is electrically insulated from lower base 241 and, together with lower base 241, sandwiches semiconductor laser element 210.

Lower base 241 is a base on which semiconductor laser element 210 is mounted. Semiconductor laser element 210 is mounted on the upper surface of lower base 241. In this embodiment, the part of the upper surface of lower base 241 on which semiconductor laser element 210 is mounted is lower than the other parts. Semiconductor laser element 210 is held by lower base 241 so as to be sandwiched between upper base 240 and lower base 241.

The material used for each of upper base 240 and lower base 241 is not limited. The material used for each of upper base 240 and lower base 241 may be, for example, a metal material, a resin material, or a ceramic material.

The respective shapes of upper base 240 and lower base 241 are not limited.

Upper base 240 and lower base 241 are fixed to each other by, for example, fitting (more specifically, screwing) screws into screw holes formed in lower base 241. Specifically, lower base 241 has screw holes. Upper base 240 has through holes at the positions corresponding to the screw holes. Screws are provided in the through holes. The screws are screwed into the screw holes.

Upper base 240 and lower base 241 may be electrically insulated. For example, an insulating material having electrical insulation is located between upper base 240 and lower base 241. The insulating material is, for example, an insulating sheet. The insulating sheet may be made of any material as long as it has electrical insulation.

Light source module 200 may have through holes that are formed through upper base 240 and lower base 241 and reach foundation 250. Screws provided in the through holes may fix upper base 240, lower base 241, and foundation 250 to each other.

Foundation 250 is a base on which driver 230 and lower base 241 are placed. The material used for foundation 250, the shape of foundation 250, etc. are not limited. Foundation 250 may be, for example, metal or ceramic. Foundation 250 may be a heat sink for dissipating heat from lower base 241. Foundation 250 may have a channel through which a liquid such as water passes. Flowing a liquid such as water through the channel can improve the heat dissipation of foundation 250.

Support 260 is a block connected to driver 230 and connected (fixed) to BTU 220. For example, support 260 is connected to BTU 220 by brazing, soldering, or the like. The material used for support 260 is not limited.

Light source module 200 may not include support 260. In this case, driver 230 is connected (fixed) to BTU 220 by brazing, soldering, or the like. The method of fixing driver 230, support 260, and BTU 220 is not limited to brazing, soldering, or the like. The fixing method may involve screws or the like, or may involve a structure of physically sandwiching without using screws, an adhesive, or the like. For example, with a structure in which driver 230 fixes BTU 220 without using an adhesive such as resin, the problem in that driver 230 cannot support BTU 220 due to degradation of an adhesive such as resin can be prevented even in the case where emission light 300 is blue to ultraviolet light having a center wavelength of about 450 nm or less.

Slow axis collimator lens 110 is a collimator lens that collimates emission light 300 emitted from BTU 220 (more specifically, optical member 222) in the slow axis direction. Slow axis collimator lens 110 collimates emission light 300 in the slow axis direction, and causes collimated emission light 300 to be incident on condensing lens 120.

Condensing lens 120 is a fast axis collimator lens that collimates incident emission light 300 in the fast axis direction. Condensing lens 120 collimates incident emission light 300 in the fast axis direction, and causes collimated emission light 300 to be incident on half mirror 130. In this embodiment, semiconductor laser element 210 emits emission light 300 so that the Y-axis direction will be the fast axis direction and the X-axis direction will be the slow axis direction.

In this embodiment, two lenses, namely, lens 221 and condensing lens 120, are used to collimate emission light 300 in the fast axis direction. Semiconductor laser device 100 may not include condensing lens 120.

Half mirror 130 is a half mirror that reflects part of light and transmits the other part of the light. The reflectance and transmittance of half mirror 130 may be set freely. Emission light 300 transmitted by half mirror 130 is incident on detector 180. Emission light 300 reflected by half mirror 130 is incident on wavelength dispersion element 140.

Wavelength dispersion element 140 is an optical element on which emission light 300 is incident and that emits a plurality of incident emission light beams 300 so as to pass through one optical path. In other words, wavelength dispersion element 140 is a multiplexer that multiplexes the plurality of emission light beams 300. Wavelength dispersion element 140 has, for example, a diffraction grating formed on the surface on which emission light 300 is incident. Emission light 300 emitted from each of the plurality of emitters 211 is incident on, for example, the diffraction grating formed on the surface of wavelength dispersion element 140, and as a result is emitted from wavelength dispersion element 140 so as to pass through one optical path. The light emitted from wavelength dispersion element 140 so as to pass through one optical path is incident on half mirror 150. Wavelength dispersion element 140 may be a transmissive wavelength dispersion element that transmits and multiplexes the plurality of emission light beams 300, or a reflective wavelength dispersion element that reflects and multiplexes the plurality of emission light beams 300.

Half mirror 150 is a half mirror that transmits part of emission light 300 emitted from semiconductor laser element 210 and reflects the other part of emission light 300 to resonate emission light 300 with semiconductor laser element 210. Reflection light 310 reflected by half mirror 150 returns to semiconductor laser element 210, and is further reflected by semiconductor laser element 210 (specifically, the surface of semiconductor laser element 210 opposite to the light emitting surface for emission light 300) and returns to half mirror 150. Reflection light 310 that has returned to half mirror 150 is further partly reflected and returns to semiconductor laser element 210. Thus, optical resonance occurs between semiconductor laser element 210 and half mirror 150. Half mirror 150 accordingly emits laser light 320 generated by an external resonator formed by semiconductor laser element 210 and half mirror 150. That is, semiconductor laser device 100 emits laser light 320.

Thus, semiconductor laser device 100 is an external resonator type semiconductor laser device that resonates emission light 300 between semiconductor laser element 210 and half mirror 150. Laser light 320 emitted from half mirror 150 is incident on condensing lens 160.

Semiconductor laser device 100 may include semiconductor laser element 210 that emits laser light by itself, instead of including the external resonator (more specifically, half mirror 150).

Condensing lens 160 is a coupling lens for causing laser light 320 to be incident on optical fiber 170. Laser light 320 emitted from condensing lens 160 is incident on one end of optical fiber 170 and is emitted from the other end of optical fiber 170.

Detector 180 is a detector that detects the intensity distribution of the light emitted from emitter 211 and transmitted through a lens (more specifically, the fast axis collimator lens included in BTU 220). In this embodiment, detector 180 detects emission light 300 transmitted through lens 221, optical member 222, slow axis collimator lens 110, condensing lens 120, and half mirror 130. Detector 180 is, for example, a camera capable of detecting the wavelength of emission light 300. Detector 180 outputs information (image) indicating the detected intensity distribution of the light to computer 190 as the detection result.

Computer 190 is a control device that controls the operation of each device included in semiconductor laser device 100. Specifically, computer 190 is communicably connected to detector 180 and driver 230 via control lines or the like, and controls the operation of each of detector 180 and driver 230. For example, computer 190 obtains the detection result from detector 180, and controls the operation of driver 230 based on the obtained detection result.

Computer 190 includes, for example, a communication interface for communicating with detector 180 and driver 230, nonvolatile memory storing a program, volatile memory serving as a temporary storage area for executing the program, an input/output port for transmitting/receiving signals, a processor for executing the program, and the like.

Computer 190 may be connected to a power source (not illustrated) or the like that supplies power to semiconductor laser element 210, via a control line. Thus, computer 190 may be communicably connected to each device included in semiconductor laser device 100.

For example, computer 190 includes controller 191 and storage 192.

Controller 191 is a processing unit that controls the operations of detector 180 and driver 230. Specifically, based on the detection result of detector 180, controller 191 controls at least one of the position or orientation of lens 221 by driving driver 230 to cause the light intensity distribution detected by detector 180 to be a predetermined light intensity distribution.

The predetermined light intensity distribution is not limited, and may be set freely beforehand. For example, the predetermined light intensity distribution is an intensity distribution suitable for wavelength dispersion element 140 to multiplex the plurality of emission light beams 300. In this embodiment, the predetermined light intensity distribution is a state in which the spots of the respective emission light beams 300 emitted from the plurality of emitters 211 overlap to form one spot. Information indicating the predetermined light intensity distribution is, for example, included in reference information 193 and stored in storage 192 beforehand. Controller 191 compares the light intensity distribution indicated by reference information 193 and the light intensity distribution detected by detector 180, and controls driver 230 based on the comparison result to control the position and orientation of lens 221.

For example, controller 191 repeatedly obtains the detection result from detector 180 and repeatedly controls driver 230 based on the obtained detection result, thus continuously adjusting the light intensity distribution indicated by the detection result to be the predetermined light intensity distribution.

In this embodiment, lens 221 is integrally formed with optical member 222. Hence, controller 191 controls driver 230 to control the positions and orientations of lens 221 and optical member 222 (i.e. BTU 220).

For example, in the case where (i) the spot of the light indicated by the detection result of detector 180 is displaced in a second detection direction corresponding to the second direction (Y-axis direction) relative to the predetermined light intensity distribution or in the case where (ii) the light indicated by the detection result of detector 180 has more spots than the predetermined light intensity distribution, controller 191 controls the position of lens 221 by causing driver 230 to move lens 221 in the first direction (X-axis direction).

For example, in the case where the spot of the light indicated by the detection result of detector 180 is displaced in a first detection direction corresponding to the first direction relative to the predetermined light intensity distribution, controller 191 controls the position of lens 221 by causing driver 230 to move lens 221 in the second direction.

For example, in the case where the light density of the whole spot of the light indicated by the detection result of detector 180 decreases relative to the predetermined light intensity distribution, controller 191 controls the position of lens 221 by causing driver 230 to move lens 221 in the emission direction (Z-axis direction).

For example, in the case where the light density of only part of the spot of the light indicated by the detection result of detector 180 decreases relative to the predetermined light intensity distribution, controller 191 controls the orientation of lens 221 by causing driver 230 to rotate lens 221 along the first rotation axis (θ_{Y1}-axis).

For example, in the case where the spot of the light indicated by the detection result of detector 180 widens in the first detection direction corresponding to the first direction relative to the predetermined light intensity distribution, controller 191 controls the orientation of lens 221 by causing driver 230 to rotate lens 221 along the second rotation axis (θ_{Z1}-axis).

Controller 191 is implemented, for example, by a control program stored in storage 192 for controlling detector 180 and driver 230, and a central processing unit (CPU) that executes the control program.

Storage 192 is a storage device that stores various data such as reference information 193 indicating the predetermined light intensity distribution, the control program executed by controller 191, etc., which are necessary for controller 191 to control driver 230.

Storage 192 is implemented, for example, by memory such as read only memory (ROM) and random access memory (RAM).

### Light Intensity Distribution

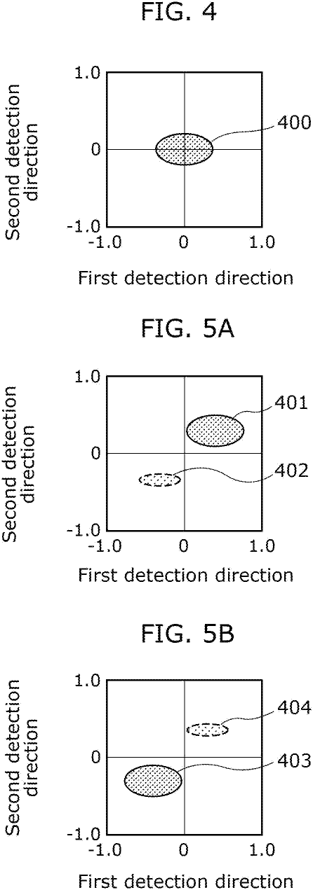

Specific examples of light intensity distributions will be described below, with reference to FIG. 4 to FIG. 9B. In FIG. 4 to FIG. 9B, the regions irradiated with light are indicated by dot hatching. The light intensity distribution may or may not be uniform in the regions irradiated with light indicated by the same dot hatching in FIG. 4 to FIG. 9B. In FIG. 4 to FIG. 9B, the horizontal axis represents the intensity of light (arbitrary unit) in the first detection direction corresponding to the first direction, and the vertical axis represents the intensity of light (arbitrary unit) in the second detection direction corresponding to the second direction.

The first detection direction corresponding to the first direction is the direction corresponding to the first direction with respect to the traveling direction of emission light 300 when emission light 300 is emitted from lens 221. For example, the first detection direction matches the first direction in an arrangement layout in which emission light 300 emitted from lens 221 is incident on detector 180 without passing through a mirror and the like, i.e. in the case where the emission surface of emission light 300 of semiconductor laser element 210 and the light receiving surface of detector 80 face each other. The second detection direction corresponding to the second direction is the direction corresponding to the second direction with respect to the traveling direction of emission light 300 when emission light 300 is emitted from lens 221. In this embodiment, the first detection direction is a direction parallel to the first direction, and the second detection direction is a direction parallel to the second direction.

Moreover, the origin is set so as to coincide with the center of the intensity distribution (light spot) of emission light 300 in the case where lens 221 is in a reference state.

### Reference State

FIG. 4 is a diagram schematically illustrating the intensity distribution of emission light 300 in the case where lens 221 is in the reference state.

The reference state of lens 221 is a state indicating the position and orientation of lens 221 in the case where an ideal light intensity distribution is detected by detector 180, like light spot 400 illustrated in FIG. 4.

For example, the layout of the structural elements included in semiconductor laser device 100 is set so that the plurality of emission light beams 300 emitted from semiconductor laser element 210 will have the light intensity distribution (light spot 400) illustrated in FIG. 4 at wavelength dispersion element 140. Specifically, at wavelength dispersion element 140, the respective irradiation positions of the plurality of emission light beams 300 emitted from semiconductor laser element 210 form one light spot. Thus, emission light beams 300 are emitted from wavelength dispersion element 140 so that their optical axes will be aligned, that is, emission light beams 300 are multiplexed.

Detector 180 is located, for example, so that its distance from condensing lens 120, which is an optical element through which emission light 300 emitted from semiconductor laser element 210 passes before reaching wavelength dispersion element 140 and that condenses (collimates) emission light 300, will be the same as the distance of wavelength dispersion element 140 from condensing lens 120. Moreover, detector 180 is located so that the optical path length from semiconductor laser element 210 to detector 180 will be the same as the optical path length from semiconductor laser element 210 to wavelength dispersion element 140. Hence, detector 180 can detect the same intensity distribution of light as the intensity distribution of the plurality of emission light beams 300 at wavelength dispersion element 140. For example, in the case where lens 221 is in the reference state, detector 180 detects light spot 400 illustrated in FIG. 4. Reference information 193 includes information indicating a light intensity distribution such as light spot 400.

For example, storage 192 stores information (reference information 193) indicating the intensity distribution of emission light 300 in the case where lens 221 illustrated in FIG. 4 is in the reference state. Based on the detection result of detector 180, controller 191 compares the intensity distribution of light detected by detector 180 and the intensity distribution (i.e. light spot 400) of reference light (i.e. light indicated by reference information 193) stored in storage 192, to calculate the deviation of the light intensity distribution detected by detector 180 from the light intensity distribution indicated by reference information 193. Based on the calculated deviation, controller 191 controls driver 230 to adjust the position and orientation of lens 221 (more specifically, BTU 220) so that the light intensity distribution detected by detector 180 will be the predetermined light intensity distribution.

### Deviation in First Direction

FIG. 5A is a diagram schematically illustrating the intensity distribution of light in the case where lens 221 deviates to the negative side of the first axis. FIG. 5B is a diagram schematically illustrating the intensity distribution of light in the case where lens 221 deviates to the positive side of the first axis.

As illustrated in FIG. 5A, in the case where lens 221 deviates to the negative side of the first axis, light spot 401 indicated by the detection result of detector 180 is displaced to the positive side in the second detection direction relative to light spot 400. Specifically, in the case where lens 221 deviates to the negative side of the first axis, the center position of light spot 401 indicated by the detection result of detector 180 is displaced to the positive side in the second detection direction relative to the center position of light spot 400. In the case where lens 221 deviates to the negative side of the first axis, the spot shape of light spot 401 indicated by the detection result of detector 180 is unchanged from the spot shape of light spot 400. Thus, in the case where lens 221 deviates to the negative side of the first axis, light spot 400 is parallelly displaced to the positive side in the second detection direction.

Moreover, in the case where lens 221 deviates to the negative side of the first axis, light spot 402 is newly detected relative to light spot 400. For example, light spot 402 is lower in light density (light intensity) than light spot 401, and is detected on the negative side in the second detection direction relative to the detection position of light spot 400. For example, light spot 401 is lower in light density than light spot 400. Thus, in the case where lens 221 deviates to the negative side of the first axis, light spot 400 is separated into light spot 401 and light spot 402.

As illustrated in FIG. 5B, in the case where lens 221 deviates to the positive side of the first axis, light spot 403 indicated by the detection result of detector 180 is displaced to the negative side in the second detection direction relative to light spot 400. Specifically, in the case where lens 221 deviates to the positive side of the first axis, the center position of light spot 403 indicated by the detection result of detector 180 is displaced to the negative side in the second detection direction relative to the center position of light spot 400. In the case where lens 221 deviates to the positive side of the first axis, the spot shape of light spot 403 indicated by the detection result of detector 180 is unchanged from the spot shape of light spot 400. Thus, in the case where lens 221 deviates to the positive side of the first axis, light spot 400 is parallelly displaced to the negative side in the second detection direction.

Moreover, in the case where lens 221 deviates to the positive side of the first axis, light spot 404 is newly detected relative to light spot 400. For example, light spot 404 is lower in light density (light intensity) than light spot 403, and is detected on the positive side in the second detection direction relative to the detection position of light spot 400. For example, light spot 403 is lower in light density than light spot 400. Thus, in the case where lens 221 deviates to the positive side of the first axis, light spot 400 is separated into light spot 403 and light spot 404.

As described above, in the case where lens 221 deviates in the first direction, (i) the spot of the light indicated by the detection result of detector 180 is displaced in the second detection direction corresponding to the second direction relative to light spot 400 as in the case of light spot 401 or 403, or (ii) the light indicated by the detection result has more spots (for example, light spot 402 or 404 is detected in addition to light spot 401 or 403) than light spot 400. Accordingly, in the case where (i) the spot of the light indicated by the detection result of detector 180 is displaced in the second detection direction corresponding to the second direction relative to light spot 400 as in the case of light spot 401 or 403 or in the case where (ii) the light indicated by the detection result has more spots than light spot 400, controller 191 controls the position of lens 221 by causing driver 230 to move lens 221 in the first direction. Hence, the light spot detected by detector 180 can be brought closer to light spot 400.

Herein, the number of spots is the number of spots larger than a predetermined diameter, and outliers detected as points or the like may be excluded from being counted in the number of spots. Moreover, in the case where the light intensity of a detected spot is lower than a predetermined intensity, the spot may be excluded from being counted in the number of spots. Partially overlapping spots may be counted as one spot or as a plurality of spots depending on the overlapping area.

### Deviation in Second Direction

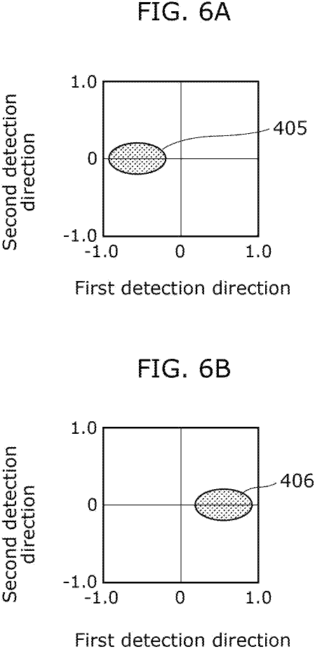

FIG. 6A is a diagram schematically illustrating the intensity distribution of light in the case where lens 221 deviates to the negative side of the second axis. FIG. 6B is a diagram schematically illustrating the intensity distribution of light in the case where lens 221 deviates to the positive side of the second axis.

As illustrated in FIG. 6A, in the case where lens 221 deviates to the negative side of the second axis, light spot 405 indicated by the detection result of detector 180 is displaced to the negative side in the first detection direction relative to light spot 400. Specifically, in the case where lens 221 deviates to the negative side of the second axis, the center position of light spot 405 indicated by the detection result of detector 180 is displaced to the negative side in the first detection direction relative to the center position of light spot 400. In the case where lens 221 deviates to the negative side of the second axis, the spot shape of light spot 405 indicated by the detection result of detector 180 is unchanged from the spot shape of light spot 400. In the case where lens 221 deviates to the negative side of the second axis, the light density of light spot 405 is unchanged from the light density of light spot 400. Thus, in the case where lens 221 deviates to the negative side of the second axis, light spot 400 is parallelly displaced to the negative side in the first detection direction.

As illustrated in FIG. 6B, in the case where lens 221 deviates to the positive side of the second axis, light spot 406 indicated by the detection result of detector 180 is displaced to the positive side in the first detection direction relative to light spot 400. Specifically, in the case where lens 221 deviates to the positive side of the second axis, the center position of light spot 406 indicated by the detection result of detector 180 is displaced to the positive side in the first detection direction relative to the center position of light spot 400. In the case where lens 221 deviates to the positive side of the second axis, the spot shape of light spot 406 indicated by the detection result of detector 180 is unchanged from the spot shape of light spot 400. In the case where lens 221 deviates to the positive side of the second axis, the light density of light spot 406 is unchanged from the light density of light spot 400. Thus, in the case where lens 221 deviates to the positive side of the second axis, light spot 400 is parallelly displaced to the positive side in the first detection direction.

As described above, in the case where lens 221 deviates in the second axis direction, the spot of the light indicated by the detection result of detector 180 is displaced in the first detection direction relative to light spot 400, as in the case of light spot 405 or 406. Accordingly, in the case where the spot of the light indicated by the detection result of detector 180 is displaced in the first detection direction corresponding to the first direction relative to light spot 400 as in the case of light spot 405 or 406, controller 191 controls the position of lens 221 by causing driver 230 to move lens 221 in the second direction. Hence, the light spot detected by detector 180 can be brought closer to light spot 400.

### Deviation in Emission Direction

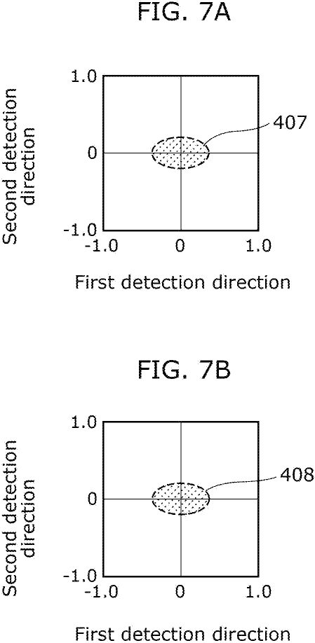

FIG. 7A is a diagram schematically illustrating the intensity distribution of light in the case where lens 221 deviates to the negative side of the emission axis. FIG. 7B is a diagram schematically illustrating the intensity distribution of light in the case where lens 221 deviates to the positive side of the emission axis.

As illustrated in FIG. 7A, in the case where lens 221 deviates to the negative side of the emission axis, light spot 407 indicated by the detection result of detector 180 is not displaced relative to light spot 400. Specifically, in the case where lens 221 deviates to the negative side of the emission axis, the center position of light spot 407 indicated by the detection result of detector 180 is not displaced relative to the center position of light spot 400. In the case where lens 221 deviates to the negative side of the emission axis, the spot shape of light spot 407 indicated by the detection result of detector 180 is unchanged from the spot shape of light spot 400. In the case where lens 221 deviates to the negative side of the emission axis, the light density of whole light spot 407 decreases relative to the light density of light spot 400.

As illustrated in FIG. 7B, in the case where lens 221 deviates to the positive side of the emission axis, light spot 408 indicated by the detection result of detector 180 is not displaced relative to light spot 400. Specifically, in the case where lens 221 deviates to the positive side of the emission axis, the center position of light spot 408 indicated by the detection result of detector 180 is not displaced relative to the center position of light spot 400. In the case where lens 221 deviates to the positive side of the emission axis, the spot shape of light spot 408 indicated by the detection result of detector 180 is unchanged from the spot shape of light spot 400. In the case where lens 221 deviates to the positive side of the emission axis, the light density of whole light spot 408 decreases relative to the light density of light spot 400.

As described above, in the case where lens 221 deviates in the emission direction, the light density of the whole spot of the light indicated by the detection result of detector 180 decreases relative to light spot 400, as in the case of light spot 407 or 408. Accordingly, in the case where the light density of the whole spot of the light indicated by the detection result of detector 180 decreases relative to light spot 400 as in the case of light spot 407 or 408, controller 191 controls the position of lens 221 by causing driver 230 to move lens 221 in the emission direction. Hence, the light spot detected by detector 180 can be brought closer to light spot 400.

### Deviation in First Rotation Direction

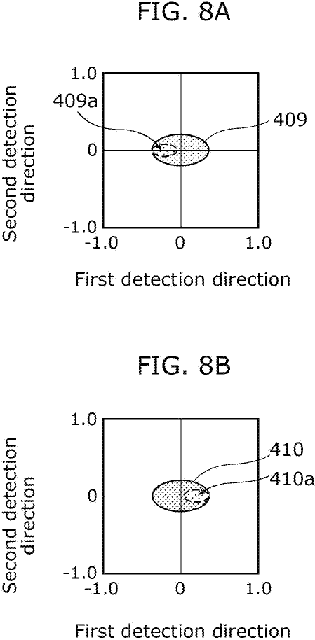

FIG. 8A is a diagram schematically illustrating the intensity distribution of light in the case where lens 221 deviates to the negative side of the first rotation axis. FIG. 8B is a diagram schematically illustrating the intensity distribution of light in the case where lens 221 deviates to the positive side of the first rotation axis.

As illustrated in FIG. 8A, in the case where lens 221 deviates to the negative side of the first rotation axis, light spot 409 indicated by the detection result of detector 180 is not displaced relative to light spot 400. Specifically, in the case where lens 221 deviates to the negative side of the first rotation axis, the center position of light spot 409 indicated by the detection result of detector 180 is not displaced relative to the center position of light spot 400. In the case where lens 221 deviates to the negative side of the first rotation axis, the spot shape of light spot 409 indicated by the detection result of detector 180 is unchanged from the spot shape of light spot 400. In the case where lens 221 deviates to the negative side of the first rotation axis, the light density of only part of light spot 409 decreases relative to the light density of light spot 400. For example, the light density of only low light density portion 409a located on the negative side of the first detection direction in light spot 409 decreases relative to light spot 400.

As illustrated in FIG. 8B, in the case where lens 221 deviates to the positive side of the first rotation axis, light spot 410 indicated by the detection result of detector 180 is not displaced relative to light spot 400. Specifically, in the case where lens 221 deviates to the positive side of the first rotation axis, the center position of light spot 410 indicated by the detection result of detector 180 is not displaced relative to the center position of light spot 400. In the case where lens 221 deviates to the positive side of the first rotation axis, the spot shape of light spot 410 indicated by the detection result of detector 180 is unchanged from the spot shape of light spot 400. In the case where lens 221 deviates to the positive side of the first rotation axis, the light density of only part of light spot 410 decreases relative to the light density of light spot 400. For example, the light density of only low light density portion 410a located on the positive side of the first detection direction in light spot 410 decreases relative to light spot 400.

As described above, in the case where lens 221 deviates in the first rotation direction (the direction along the first rotation axis), the light density of only part of the spot of the light indicated by the detection result of detector 180 decreases relative to light spot 400, as in the case of light spot 409 or 410. Accordingly, in the case where the light density of only part of the spot of the light indicated by the detection result of detector 180 decreases relative to light spot 400 as in the case of light spot 409 or 410, controller 191 controls the position of lens 221 by causing driver 230 to move lens 221 in the first rotation direction. Hence, the light spot detected by detector 180 can be brought closer to light spot 400.

### Deviation in Second Rotation Direction

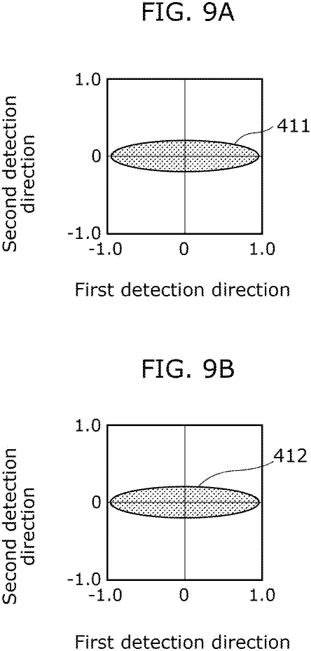

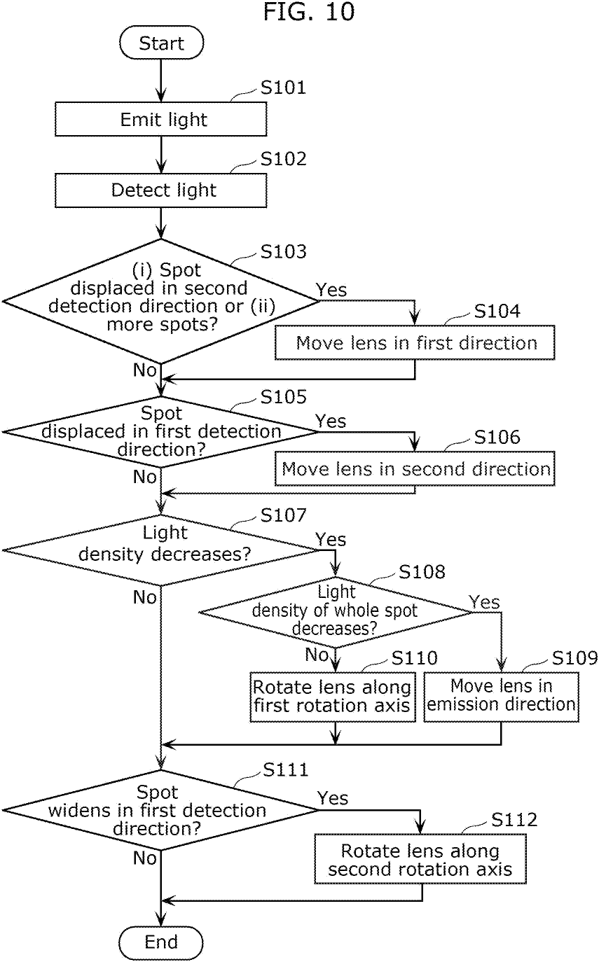

FIG. 9A is a diagram schematically illustrating the intensity distribution of light in the case where lens 221 deviates to the negative side of the second rotation axis. FIG. 9B is a diagram schematically illustrating the intensity distribution of light in the case where lens 221 deviates to the positive side of the second rotation axis.

As illustrated in FIG. 9A, in the case where lens 221 deviates to the negative side of the second rotation axis, light spot 411 indicated by the detection result of detector 180 is not displaced relative to light spot 400. Specifically, in the case where lens 221 deviates to the negative side of the second rotation axis, the center position of light spot 411 indicated by the detection result of detector 180 is not displaced relative to the center position of light spot 400. In the case where lens 221 deviates to the negative side of the second rotation axis, the spot shape of light spot 411 indicated by the detection result of detector 180 widens in the first detection direction relative to the spot shape of light spot 400.

As illustrated in FIG. 9B, in the case where lens 221 deviates to the positive side of the second rotation axis, light spot 412 indicated by the detection result of detector 180 is not displaced relative to light spot 400. Specifically, in the case where lens 221 deviates to the positive side of the second rotation axis, the center position of light spot 412 indicated by the detection result of detector 180 is not displaced relative to the center position of light spot 400. In the case where lens 221 deviates to the positive side of the second rotation axis, the spot shape of light spot 412 indicated by the detection result of detector 180 widens in the first detection direction relative to the spot shape of light spot 400.

As described above, in the case where lens 221 deviates in the second rotation direction (the direction along the second rotation axis), the spot of the light indicated by the detection result of detector 180 widens in the first detection direction corresponding to the first direction relative to light spot 400, as in the case of light spot 411 or 412. Accordingly, in the case where the spot of the light indicated by the detection result of detector 180 widens in the first detection direction corresponding to the first direction relative to light spot 400 as in the case of light spot 411 or 412, controller 191 controls the position of lens 221 by causing driver 230 to move lens 221 in the second rotation direction. Hence, the light spot detected by detector 180 can be brought closer to light spot 400.

### Procedure

A procedure by semiconductor laser device 100 will be described below, with reference to FIG. 10.

First, semiconductor laser device 100 emits emission light 300 (Step S101). For example, controller 191 controls a power source (not illustrated) to supply power to semiconductor laser element 210, thus causing each of the plurality of emitters 211 included in semiconductor laser element 210 to emit emission light 300.

Next, detector 180 detects the intensity distribution of emission light 300 (Step S102). Detector 180 outputs information indicating the detected intensity distribution of emission light 300 to controller 191.

Next, controller 191 determines whether (i) the spot of the light indicated by the detection result of detector 180 is displaced in the second detection direction corresponding to the second direction relative to the predetermined light intensity distribution, and whether (ii) the light indicated by the detection result has more spots than the predetermined light intensity distribution (Step S103).

In the case where controller 191 determines that (i) the spot of the light indicated by the detection result of detector 180 is displaced in the second detection direction corresponding to the second direction relative to the predetermined light intensity distribution or (ii) the light indicated by the detection result has more spots than the predetermined light intensity distribution (Step S103: Yes), controller 191 controls the position of lens 221 by causing driver 230 to move lens 221 in the first direction (Step S104).

In the case where controller 191 determines that (i) the spot of the light indicated by the detection result of detector 180 is not displaced in the second detection direction corresponding to the second direction relative to the predetermined light intensity distribution and (ii) the light indicated by the detection result does not have more spots than the predetermined light intensity distribution (Step S103: No) or after controller 191 executes Step S104, controller 191 determines whether the spot of the light indicated by the detection result of detector 180 is displaced in the first detection direction corresponding to the first direction relative to the predetermined light intensity distribution (Step S105).

In the case where controller 191 determines that the spot of the light indicated by the detection result of detector 180 is displaced in the first detection direction corresponding to the first direction relative to the predetermined light intensity distribution (Step S105: Yes), controller 191 controls the position of lens 221 by causing driver 230 to move lens 221 in the second direction (Step S106).

In the case where controller 191 determines that the spot of the light indicated by the detection result of detector 180 is not displaced in the first detection direction corresponding to the first direction relative to the predetermined light intensity distribution (Step S105: No) or after controller 191 executes Step S106, controller 191 determines whether the light density of the spot of the light indicated by the detection result of detector 180 decreases relative to the predetermined light intensity distribution (Step S107).

In the case where controller 191 determines that the light density of the spot of the light indicated by the detection result of detector 180 decreases relative to the predetermined light intensity distribution (Step S107: Yes), controller 191 determines whether the light density of the whole spot of the light indicated by the detection result of detector 180 decreases relative to the predetermined light intensity distribution (Step S108).

In the case where controller 191 determines that the light density of the whole spot of the light indicated by the detection result of detector 180 decreases relative to the predetermined light intensity distribution (Step S108: Yes), controller 191 controls the position of lens 221 by causing driver 230 to move lens 221 in the emission direction (Step S109).

In the case where controller 191 determines that the light density of the whole spot of the light indicated by the detection result of detector 180 does not decrease relative to the predetermined light intensity distribution (Step S108: No), that is, in the case where controller 191 determines that the light density of only part of the spot of the light indicated by the detection result of detector 180 decreases relative to the predetermined light intensity distribution, controller 191 controls the orientation of lens 221 by causing driver 230 to rotate lens 221 along the first rotation axis (Step S110).

In the case where controller 191 determines that the light density of the spot of the light indicated by the detection result of detector 180 does not decrease relative to the predetermined light intensity distribution (Step S107: No) or after controller 191 executes Step S109 or Step S110, controller 191 determines whether the spot of the light indicated by the detection result of detector 180 widens in the first detection direction corresponding to the first direction relative to the predetermined light intensity distribution (Step S111).

In the case where controller 191 determines that the spot of the light indicated by the detection result of detector 180 widens in the first detection direction corresponding to the first direction relative to the predetermined light intensity distribution (Step S111: Yes), controller 191 controls the orientation of lens 221 by causing driver 230 to rotate lens 221 along the second rotation axis (Step S112).

In the case where controller 191 determines that the spot of the light indicated by the detection result of detector 180 does not widen in the first detection direction corresponding to the first direction relative to the predetermined light intensity distribution (Step S111: No) or after controller 191 executes Step S112, controller 191 ends the procedure.

For example, controller 191 repeatedly executes Steps S102 to S112 described above at certain timing while causing emitter 211 to keep emitting emission light 300.

Half mirror 130 may be a shutter capable of switching between reflection and transmission of emission light 300. For example, controller 191 may control the shutter to reflect emission light 300 at the timing when detector 180 does not detect emission light 300, and control the shutter to transmit emission light 300 at the timing when detector 180 detects emission light 300.

In this way, it is possible to prevent part of emission light 300 from traveling to detector 180 at the timing when detector 180 does not detect emission light 300.

### Effects, Etc

As described above, semiconductor laser device 100 according to the embodiment includes: semiconductor laser element 210 including emitter 211 that emits emission light 300; lens 221 that transmits emission light 300 emitted from emitter 211; driver 230 that supports lens 221 in a state in which a position and an orientation of lens 221 are changeable; detector 180 that detects an intensity distribution of emission light 300 emitted from emitter 211 and transmitted through lens 221; and controller 191 that, based on a detection result of detector 180, controls at least one of the position or the orientation of lens 221 by driving driver 230 to cause the intensity distribution of the light detected by detector 180 to be a predetermined light intensity distribution.

With this, for example, controller 191 can determine whether the light emitted from emitter 211 has the appropriate intensity distribution by comparing the detection result of detector 180 and reference information 193 indicating the predetermined light intensity distribution. For example, in the case where the predetermined light intensity distribution and the intensity distribution of the light emitted from emitter 211 are different, i.e. in the case where the light emitted from emitter 211 does not have the appropriate intensity distribution, controller 191 can adjust the light emitted from emitter 211 to have the appropriate intensity distribution by controlling at least one of the position or the orientation of lens 221. Semiconductor laser device 100 can thus maintain the relative positional relationship between semiconductor laser element 210 that emits emission light 300 and lens 221 that transmits emission light 300, in the appropriate state.

For example, semiconductor laser device 100 further includes: optical member 222 that switches a fast axis direction and a slow axis direction of emission light 300 output from lens 221.

With this, for example, the fast axis direction of emission light 300 emitted from semiconductor laser element 210 can be changed from the second direction to the first direction. This can improve the degree of freedom in selecting the layout and the shapes such as sizes of lens 221 and slow axis collimator lens 110 included in semiconductor laser device 100.

For example, driver 230 is a magnetic actuator.

The adjustment of the position and orientation of lens 221 is made in the order of micrometers. As a result of driver 230 being a magnetic actuator, the position and the orientation can be finely controlled easily.

For example, lens 221 is a fast axis collimator lens that collimates emission light 300 emitted from emitter 211 in a fast axis direction.

With this, emission light 300 emitted from semiconductor laser element 210 can be prevented from widening in the fast axis direction.

For example, semiconductor laser element 210 includes a plurality of emitters 211.

With this, for example, the light amount (light density) of laser light 320 emitted from semiconductor laser device 100 can be increased by multiplexing emission light beams 300.

For example, driver 230 is an actuator capable of adjusting five axes: an emission axis (Z1 axis) that is an axis parallel to an emission direction of emission light 300 of emitter 211; a first axis (X1 axis) that is an axis parallel to a first direction in which the plurality of emitters 211 are arranged; a second axis (Y1 axis) that is an axis parallel to a second direction orthogonal to each of the emission axis and the first axis; a first rotation axis (θ_{Y1} axis) that is an axis of a rotation direction about the second axis; and a second rotation axis (θ_{Z1} axis) that is an axis of a rotation direction about the emission axis.

As a result of careful examination, the present inventors found out that changing the orientation of lens 221 about the rotation axis of the rotation direction about the first axis does not significantly affect the intensity distribution of light. In other words, as a result of careful examination, the present inventors found out that the intensity distribution of light can be easily adjusted to the appropriate intensity distribution by controlling the position and orientation of lens 221 using the foregoing five axes. That is, regardless of how the intensity distribution of light detected by detector 180 deviates from the predetermined light intensity distribution, controller 191 can easily adjust the intensity distribution of light to the appropriate intensity distribution by controlling the position and orientation of lens 221 using the foregoing five axes.

In this embodiment, for example, semiconductor laser device 100 includes semiconductor laser element 210, lens 221, driver 230, detector 180, controller 191, and optical member 222. Lens 221 is a fast axis collimator lens, and semiconductor laser element 210 includes a plurality of emitters 211 arranged in a line in a first direction. Detector 180 detects an intensity distribution of light emitted from each of the plurality of emitters 211 and transmitted through lens 221 and optical member 222. Driver 230 is an actuator capable of adjusting the foregoing five axes.

With such a structure, for example, controller 191 controls the position of lens 221 by causing driver 230 to move lens 221 in the first direction, when (i) a spot of the light indicated by the detection result of detector 180 is displaced in a second detection direction corresponding to the second direction relative to the predetermined light intensity distribution or when (ii) the light indicated by the detection result of detector 180 has more spots than the predetermined light intensity distribution.

For example, controller 191 controls the position of lens 221 by causing driver 230 to move lens 221 in the second direction, when a spot of the light indicated by the detection result of detector 180 is displaced in a first detection direction corresponding to the first direction relative to the predetermined light intensity distribution.

For example, controller 191 controls the position of lens 221 by causing driver 230 to move lens 221 in the emission direction, when a light density of a whole spot of the light indicated by the detection result of detector 180 decreases relative to the predetermined light intensity distribution.

For example, controller 191 controls the orientation of lens 221 by causing driver 230 to rotate lens 221 along the first rotation axis, when a light density of only part of a spot of the light indicated by the detection result of detector 180 decreases relative to the predetermined light intensity distribution.

For example, controller 191 controls the orientation of lens 221 by causing driver 230 to rotate lens 221 along the second rotation axis, when a spot of the light indicated by the detection result of detector 180 widens in a first detection direction corresponding to the first direction relative to the predetermined light intensity distribution.

As a result of careful examination, the present inventors found out how the position and orientation of lens 221 are to be adjusted in response to how the light intensity distribution changes, to achieve the predetermined light intensity distribution. Hence, controller 191 can maintain the relative positional relationship between semiconductor laser element 210 that emits emission light 300 and lens 221 that transmits emission light 300 in the appropriate state, based on the detection result of detector 180.

### Variations

Light source module 200 included in semiconductor laser device 100 is not limited to the above-described structure.

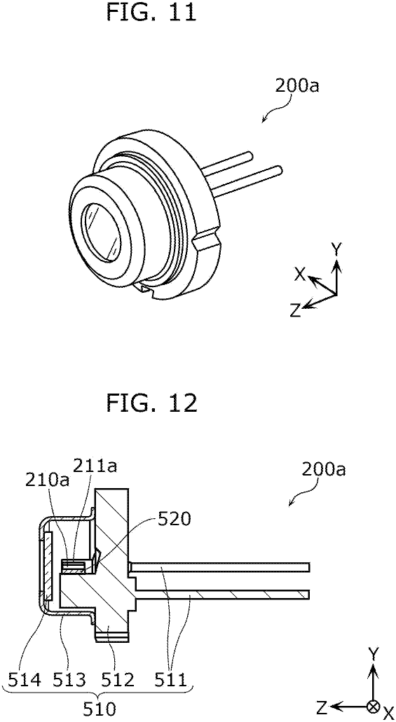

FIG. 11 is a perspective diagram illustrating light source module 200a according to a variation. FIG. 12 is a sectional diagram illustrating light source module 200a according to the variation. The differences between light source module 200 and light source module 200a will be mainly described below.

Light source module 200a includes semiconductor laser element 210a, package 510, and submount 520.

Semiconductor laser element 210a differs from semiconductor laser element 210 in the number of emitters included. Specifically, semiconductor laser element 210a includes one emitter 211a.

Thus, the semiconductor laser element included in semiconductor laser device 100 may be semiconductor laser element 210a having one emitter 211a or semiconductor laser element 210 having a plurality of emitters 211.

As a result of semiconductor laser device 100 including semiconductor laser element 210a having one emitter 211a, the number of parts of semiconductor laser element 210a from which light is emitted can be limited to one. In other words, the number of laser light beams emitted from semiconductor laser element 210a can be limited to one. Therefore, the size of BTU 220 can be reduced as compared with when light is emitted from a plurality of parts as in semiconductor laser element 210.

Package 510 is a housing that contains semiconductor laser element 210a. Package 510 is a CAN package. Package 510 includes lead pins 511, stem 512, window 513, and cap 514.

Lead pins 511 are pins for receiving power supplied from the outside of package 510 to semiconductor laser element 210a. Lead pins 511 are fixed to stem 512. Lead pins 511 are made of, for example, a conductive metal material.

Stem 512 is a table on which semiconductor laser element 210a is placed. In this embodiment, semiconductor laser element 210a is mounted on stem 512 via submount 520. Stem 512 is made of, for example, a metal material.

Window 513 is a translucent member that transmits light emitted from semiconductor laser element 210a. Window 513 is formed of, for example, a translucent resin material or a low-reflectance member having a dielectric multilayer film. For example, in the case where semiconductor laser element 210a emits short-wavelength laser light, a member obtained by forming a dielectric multilayer film on a transparent material such as glass or quartz is used as window 513 in order to suppress degradation.

Cap 514 is a member provided in contact with stem 512 so as to cover semiconductor laser element 210a. Cap 514 has a through hole. Light is emitted from semiconductor laser element 210a through the through hole to the outside of package 510. For example, window 513 is provided so as to cover the through hole. Stem 512, window 513, and cap 514 hermetically seal semiconductor laser element 210a, for example.

Submount 520 is a substrate on which semiconductor laser element 210a is placed. Submount 520 is made of, for example, a ceramic material.

As described above, the housing for supporting and containing the semiconductor laser element included in semiconductor laser device 100 is not limited and may be implemented by package 510 or bases (upper base 240, lower base 241, etc.).

Semiconductor laser device 100 may include a light source module including semiconductor laser element 210 and package 510, or include a light source module including semiconductor laser element 210a and bases (upper base 240, lower base 241, etc.). That is, the light source module included in semiconductor laser device 100 may be implemented by any combination of components of light source module 200 and light source module 200a.

### Other Embodiments

While a semiconductor laser device according to the present disclosure has been described above by way of embodiments and variations, the present disclosure is not limited to such embodiments variations. Other modifications obtained by applying various changes conceivable by a person skilled in the art to the embodiments and any combinations of the elements in different embodiments without departing from the scope of the present disclosure are also included in the scope of one or more aspects.

Part or all of the structural elements included in computer 190 according to the foregoing embodiment may be configured in the form of an exclusive hardware product, or may be implemented by executing a software program suitable for the structural elements. Each of the structural elements may be implemented by means of a program executing unit, such as a center processing unit (CPU) or a processor, reading and executing the software program recorded on a recording medium such as a hard disk drive (HDD) or semiconductor memory.

The structural elements of computer 190 may be composed of one or more electronic circuits. Each of the one or more electronic circuits may be a general-purpose circuit or a dedicated circuit.

One or more electronic circuits may include, for example, a semiconductor device, an integrated circuit (IC), or a large scale integration (LSI). An IC or LSI may be integrated on one chip or integrated on a plurality of chips. Although they are called IC or LSI here, they may be called system LSI, very large scale integration (VLSI), or ultra large scale integration (ULSI) depending on the degree of integration. A field programmable gate array (FPGA) that is programmed after the production of LSI can also be used for the same purpose.

### INDUSTRIAL APPLICABILITY

The semiconductor laser device according to the present disclosure can be used for a light source used for laser processing, particularly a light source of a laser beam machine using a semiconductor laser device for direct processing.

1. A semiconductor laser device comprising:
a semiconductor laser element including an emitter that emits light;
a lens that transmits the light emitted from the emitter;
a driver that supports the lens in a state in which a position and an orientation of the lens are changeable;
a detector that detects an intensity distribution of the light emitted from the emitter and transmitted through the lens; and
a controller that, based on a detection result of the detector, controls at least one of the position or the orientation of the lens by driving the driver to cause the intensity distribution of the light detected by the detector to be a predetermined light intensity distribution.

2. The semiconductor laser device according to claim 1, further comprising:
an optical member that switches a fast axis direction and a slow axis direction of the light output from the lens.

3. The semiconductor laser device according to claim 2,
wherein the lens and the optical member are in contact with each other.

4. The semiconductor laser device according to claim 1,
wherein the driver is a magnetic actuator.

5. The semiconductor laser device according to claim 1,
wherein the lens is a fast axis collimator lens that collimates the light emitted from the emitter in a fast axis direction.

6. The semiconductor laser device according to claim 1,
wherein the emitter included in the semiconductor laser element comprises a plurality of emitters.

7. The semiconductor laser device according to claim 6,
wherein the driver is an actuator capable of adjusting five axes: an emission axis that is an axis parallel to an emission direction of the light of the emitter; a first axis that is an axis parallel to a first direction in which the plurality of emitters are arranged; a second axis that is an axis parallel to a second direction orthogonal to each of the emission axis and the first axis; a first rotation axis that is an axis of a rotation direction about the second axis; and a second rotation axis that is an axis of a rotation direction about the emission axis.

8. The semiconductor laser device according to claim 1, further comprising:
an optical member that switches a fast axis direction and a slow axis direction of the light output from the lens,
wherein the lens is a fast axis collimator lens that collimates the light emitted from the emitter in the fast axis direction,
the emitter included in the semiconductor laser element comprises a plurality of emitters that are arranged in a line in a first direction orthogonal to an emission direction of the light of the emitter,
the detector detects an intensity distribution of light emitted from each of the plurality of emitters and transmitted through the lens and the optical member, and
the driver is an actuator capable of adjusting five axes: an emission axis that is an axis parallel to the emission direction of the light of the emitter; a first axis that is an axis parallel to the first direction; a second axis that is an axis parallel to a second direction orthogonal to each of the emission axis and the first axis; a first rotation axis that is an axis of a rotation direction about the second axis; and a second rotation axis that is an axis of a rotation direction about the emission axis.

9. The semiconductor laser device according to claim 8,
wherein the controller controls the position of the lens by causing the driver to move the lens in the first direction, when (i) a spot of the light indicated by the detection result is displaced in a second detection direction corresponding to the second direction relative to the predetermined light intensity distribution or when (ii) the light indicated by the detection result has more spots than the predetermined light intensity distribution.

10. The semiconductor laser device according to claim 8,
wherein the controller controls the position of the lens by causing the driver to move the lens in the second direction, when a spot of the light indicated by the detection result is displaced in a first detection direction corresponding to the first direction relative to the predetermined light intensity distribution.

11. The semiconductor laser device according to claim 8,
wherein the controller controls the position of the lens by causing the driver to move the lens in the emission direction, when a light density of a whole spot of the light indicated by the detection result decreases relative to the predetermined light intensity distribution.

12. The semiconductor laser device according to claim 8,
wherein the controller controls the orientation of the lens by causing the driver to rotate the lens along the first rotation axis, when a light density of only part of a spot of the light indicated by the detection result decreases relative to the predetermined light intensity distribution.

13. The semiconductor laser device according to claim 8,
wherein the controller controls the orientation of the lens by causing the driver to rotate the lens along the second rotation axis, when a spot of the light indicated by the detection result widens in a first detection direction corresponding to the first direction relative to the predetermined light intensity distribution.
